(19) United States
(12) Patent Application Publication
(10) Pub. No.: US 2016/0118444 A1
(43) Pub. Date: Apr. 28, 2016

(54) ORGANIC P-N JUNCTION BASED INFRARED DETECTION DEVICE AND MANUFACTURING METHOD THEREOF AND INFRARED IMAGE DETECTOR USING SAME

(71) Applicant: Shenzhen China Star Optoelectronics Technology Co., Ltd., Shenzhen, Guangdong (CN)

(72) Inventor: Yawei LIU, Shenzhen City, Guangdong (CN)

(21) Appl. No.: 14/118,228

(22) PCT Filed: Jul. 24, 2013
(86) PCT No.: PCT/CN13/80055

§ 371 Date: Nov. 17, 2013

(30) Foreign Application Priority Data
Jul. 17, 2013 (CN) 201310300607.7

(51) Int. Cl. H01L 27/30; H01L 51/44; H04N 5/33

(52) U.S. Cl. CPC H01L 27/307; H04N 5/33; H01L 51/448

(57) ABSTRACT

The present invention provides an organic p-n junction based infrared detection device and a manufacturing method thereof and an infrared image detector using the device. The organic p-n junction based infrared detection device (40) includes: an active glass substrate (42) and a packaging glass substrate (44) that are arranged to be parallel to and opposite to each other, a plurality of organic p-n junctions (43) arranged between the active glass substrate (42) and the packaging glass substrate (44), and a package material (48) arranged on a circumferential marginal area of the active glass substrate (42) and the packaging glass substrate (44). The plurality of organic p-n junctions (43) is arranged in the form of a matrix on the active glass substrate (42). Based on the organic p-n junctions, the present invention has a simple manufacturing process and low material toxicity and is inexpensive, diversified, and of various sources and the infrared image detector can be manufactured on a flexible substrate and can expand the imaging angle.

### BACKGROUND OF THE INVENTION

1. Field of the Invention

The present invention relates to the field of infrared detection, and in particular to an organic p-n junction based infrared detection device and a manufacturing method thereof and an infrared image detector using the device.

2. The Related Arts

Infrared light is an electromagnetic wave having a wavelength range between microwave and visible light, the wavelength being between 760 nanometers and 1 millimeter, and is an invisible light having a wavelength greater than red light. Infrared light is commonly used in communication, survey, medical therapy, and military. For example, window wavelengths of optic fiber communication, including 850 nm, 1,130 nm, and 1,550 nm, are all located in the infrared waveband. Further, the infrared waveband also relates to applications of data processing, storage, security marking, infrared survey, and infrared aiming.

An infrared detector is a device that converts an incident infrared signal into an electrical signal. Infrared light has a wavelength between visible light and microwave and is invisible to human eyes. To perceive the existence of an infrared light and to detect the intensity thereof, the infrared light must be converted into another physical quantity that can be perceived and measured. Generally, any effect that caused by irradiating an infrared light onto an object can be used to measure the intensity of the infrared if such an effect provides a result that is a measurable result with sufficient sensitivity. A modern infrared detector takes advantage of the thermal effect and photoelectric effect of infrared and the outputs of these effects are quantity of electricity or can be converted through a proper means into quantity of electricity. Technology that is applied to detect and convert an invisible infrared light into a measurable signal is called infrared detection technology.

The infrared detection technology possesses the following advantages:

(1) It shows better environmental adaptability than visible lights, particularly the capability thereof for operating in nighttime and bad weather;

(2) It shows excellent hideability and it generally receives a signal from a target in a passive manner so as to be of better safety and security than radar and laser detection and being not easily interfered with;

(3) Detection is made on the basis of infrared radiation characteristics resulting from temperature difference and emissivity difference between a target and the background so that the capability of identifying a masqueraded target is better than the visible lights;

(4) Compared to a radar system an infrared system has various advantages, including small size, light weight, and small power consumption;

(5) The detector has been developed from single cell to multiple cells and further from multiple cells to focal plane to thereby provide various detectors and systems and has been developed from a single waveband to multiple waveband detection, from cooled type detectors to ambient temperature detectors, and spectral response being expanded from short wave to long wave;

(6) Due to the unique advantages of infrared detection, it has been widely researched and used in military, defense, and civil fields and is particularly driven by the military needs and pushed by the development of associated techniques so that the infrared detection technology, which provides novel techniques is of even wider application in the future and shows a more sound basis.

The conventional infrared detectors are classified as thermal infrared detectors and photoelectric infrared detectors.

A photoelectric infrared detector absorbs photons and changes electron state thereof to induce photo effect including internal photoelectric effect and external photoelectric effect. The intensity of the photon effect can be used to measure the number of the photons that are absorbed. The photoelectric infrared detector can be specifically classified as a photoconductive detector, a photovoltaic detector, a light emission Schottky barrier detector, and a quantum well infrared photo-detector (QWIP). The costs the materials that are used to make the conventional photoelectric infrared detector are high and the manufacturing costs are high.

A thermal infrared detector absorbs infrared light and induces a temperature rise to have a detecting material inducing a thermal electromotive force, a variation of resistivity, variation of intensity of spontaneous polarization, or gas volume variation or pressure variation, whereby through measurement of the variation of the physical properties, energy or power of the absorbed infrared radiation can be detected. By applying the above-described characteristics, various thermal detectors can be made.

The fast progress of infrared focal plane array technology drives the Western developed countries, such as USA, UK, France, Germany, Japan, Canada, and Israel, to develop and manufacture more advanced infrared focal plane array photographing devices, among which USA takes a leading position in the development of infrared focal plane transducers with the scale of the focal plane array being as large as 2048×2048 cells, close to visible light silicon.

As to charge-coupled device (CCD) photographing arrays, Japan is the first one that achieves a single chip infrared focal plane array in which 100 millions of pixels are integrated. As to the types, various products are available in the market, from HgCdTe, InSb, GaAlAs/GaAs quantum well and PtSi to non-cooled infrared focal plane array to grasp commercial opportunities. Recently, infrared imaging techniques of China has been greatly advanced and the gap with respect to the technical level of the Western countries is gradually narrowed down. Some of the advanced devices are at the same technical level as the Western countries. For example, it is currently possible to make 1000×1000 pixel detector arrays that have an area less than 30 μm². Since novel indium antimonide components have been adopted, currently, it is possible to achieve a resolution of less than 0.01° C. temperature difference so that the current resolution has already achieved an even higher level.

However, the thermal infrared imaging techniques have the following disadvantages:

(1) Image contrast is low and the capability of identifying details is poor.

Since thermal infrared imaging can only form an image according to temperature difference and since the temperature difference of a target is generally not great, the contrast of infrared imaging is low, making the capability of identifying details poor.

(2) It cannot clearly observe a target through a transparent obstacle, such as a window glass.

Since thermal infrared imaging general relies on temperature difference, a transparent obstacle, such as a window glass, may make it impossible for an infrared imaging device to detect the temperature difference of an object behind the obstacle so that it is not possible to clearly observe a target through a transparent obstacle.

(3) it is of a high cost and expensive price.

Currently, cost is the most important factor that prevents thermal infrared imaging device from wide use.

(4) HgCdTe, InSb, GaAlAs/GaAs quantum well and Ptsi inorganic semiconductor infrared detectors suffer complicated manufacturing process, materials being expensive and toxicant, and incapability of being manufactured on polycrystalline, amorphous, and flexible plastic substrates.

### SUMMARY OF THE INVENTION

An object of the present invention is to provide an organic p-n junction based infrared detection device, which is made of an organic material and the material is of low toxicity, inexpensive, diversified, and of various sources and the infrared detection device can be manufactured on a flexible substrate to expand the imaging angle.

Another object of the present invention is to provide a manufacturing method of an organic p-n junction based infrared detection device, wherein the manufacture is easy, the manufacture cost is low, and the method can be used to manufacture an infrared detection device on a flexible substrate to expand the imaging angle.

A further object of the present invention is to provide an infrared image detector, which uses an organic p-n junction based infrared detection device, wherein the manufacture is easy, the manufacture cost is low, the material used is of low toxicity, inexpensive, diversified, and of various sources and the infrared image detector has an expanded imaging angle.

To achieve the object, the present invention provides an organic p-n junction based infrared detection device, which comprises: an active glass substrate and a packaging glass substrate that are arranged to be parallel to and opposite to each other, a plurality of organic p-n junctions arranged between the active glass substrate and the packaging glass substrate, and a package material arranged on a circumferential marginal area of the active glass substrate and the packaging glass substrate. The plurality of organic p-n junctions is arranged in a matrix on the active glass substrate.

Each of the organic p-n junctions comprises: an anode mounted on the active glass substrate, an organic material layer arranged on the anode, and a cathode arranged on the organic material layer. The cathode and the packaging glass substrate are positioned against each other.

The organic material layer comprises an organic p-type material and an organic n-type material. The organic p-type material is an infrared absorbing material and the infrared absorbing material comprises copper hexadecafluorophthalocyanine or DCDSTCY. The organic n-type material comprises a fullerene derivative.

The present invention also provides a manufacturing method of an organic p-n junction based infrared detection device, which comprises the following steps:

(1) providing a glass substrate and depositing an indium tin oxide (ITO) layer on the glass substrate;

(2) using photolithography to patternize the indium tin oxide layer so as to form a plurality of anodes that is arranged in a matrix;

(3) forming an organic material layer on each of the anodes;

(4) forming a cathode on each of the organic material layers; and

(5) providing a packaging glass substrate and using a package material to bond the packaging glass substrate and the glass substrate on which the indium tin oxide layer is formed to form an organic p-n junction based infrared detection device.

In step (3), co-evaporation of vacuum deposition technology is used to simultaneously deposit an organic p-type material and an organic n-type material on each of the anodes to form the organic material layer; or, in step (3), vacuum deposition is adopted to first deposit an organic p-type material on each of the anodes and then, a layer of organic n-type material is deposited on the organic p-type material to form the organic material layer, wherein a ratio between the organic p-type material and the organic n-type material is 5-7:3-5 and after the deposition, the organic p-type material shows a thickness of 30-150 nanometers and the organic n-type material has a thickness of 20-50 nanometers.

In step (3), an organic p-type material and an organic n-type material are collectively dissolved in an organic solvent and then, a mask and the indium tin oxide layer are laminated together and the organic solvent in which the organic p-type material and the organic n-type material are dissolved is applied on the mask, and after the organic solvent is dried, the mask is removed to thus form the organic material layer, wherein a ratio between the organic p-type material and the organic n-type material is 5-7:3-5.

In step (5), a resin frame is applied on a circumferential edge of the packaging glass substrate and the packaging glass substrate on which the resin frame is applied and the glass substrate on which the indium tin oxide layer is formed are laminated together and are subjected to irradiation of ultraviolet light to cure the resin frame thereby hermetically package the packaging glass substrate and the glass substrate on which the indium tin oxide layer is formed together; or, a meltable adhesive or a metal adhesive is applied on a circumferential edge of the packaging glass substrate and the adhesive is heated and dried, and the glass substrate on which the indium tin oxide layer is formed and the packaging glass substrate are assembled together, and carbon dioxide (CO₂) laser or infrared laser having a laser wavelength of 800-1200 nm is applied to melt the dried adhesive so as to hermetically bond the glass substrate on which the indium tin oxide layer is formed and the packaging glass substrate together.

The organic material layer comprises an organic p-type material and an organic n-type material. The organic p-type material is an infrared absorbing material and the infrared absorbing material comprises copper hexadecafluorophthalocyanine or DCDSTCY. The organic n-type material comprising a fullerene derivative.

The present invention further provides an infrared image detector using an organic p-n junction based infrared detection device, which comprises: an enclosure, an infrared-pass filter mounted on the enclosure, an organic p-n junction based infrared detection device mounted in the enclosure and corresponding to the infrared-pass filter, a circuit structure mounted in the enclosure and electrically connected to the organic p-n junction based infrared detection device, and a display device mounted on the enclosure and electrically connected to the circuit structure. The organic p-n junction based infrared detection device comprises: an active glass substrate and a packaging glass substrate that are arranged to be parallel to and opposite to each other, a plurality of organic p-n junctions arranged between the active glass substrate and the packaging glass substrate, and a package material arranged on a circumferential marginal area of the active glass substrate and the packaging glass substrate. The plurality of organic p-n junctions is arranged in the form of a matrix on the active glass substrate. The circuit structure comprises: a photo current receiving and amplifying module electrically connected to the organic p-n junction based infrared detection device and a display driving module electrically connected to the photo current receiving and amplifying module. The display driving module is further electrically connected to the display device.

The active glass substrate of the organic p-n junction based infrared detection device is arranged to face the infrared-pass filter. The enclosure comprises a first opening and a second opening formed thereon. The infrared-pass filter is mounted in the first opening. The display device is mounted in the second opening. Each of the organic p-n junctions comprises: an anode mounted on the active glass substrate, an organic material layer arranged on the anode, and a cathode arranged on the organic material layer. The cathode and the packaging glass substrate are positioned against each other. The organic material layer comprises an organic p-type material and an organic n-type material. The organic p-type material is an infrared absorbing material and the infrared absorbing material comprises copper hexadecafluorophthalocyanine or DCDSTCY. The organic n-type material comprises a fullerene derivative.

The efficacy of the present invention is that the present invention provides an organic p-n junction based infrared detection device and a manufacturing method thereof and an infrared image detector using the device, wherein organic p-n junctions absorb radiating photons of an infrared light to form excitons (electron-hole pairs) and the excitons separate at the interface between the organic p material and the organic n material to allow the electrons to flow to the cathode and the holes flowing to the anode, so as to form a photo current, and a circuit structure receives the photo current, which is subjected to amplification to finally display a monochromatic image that is visible to human eyes on a display device. The image has a high contrast and a strong power for identifying details. The infrared detection device has a simple manufacturing process and a low manufacturing cost and the materials used are of low toxicity, inexpensive, diversified, and of various sources and the infrared detection device can be manufactured on a polycrystalline, amorphous, flexible substrate and can expand the imaging angle.

For better understanding of the features and technical contents of the present invention, reference will be made to the following detailed description of the present invention and the attached drawings. However, the drawings are provided for the purposes of reference and illustration and are not intended to impose undue limitations to the present invention.

### BRIEF DESCRIPTION OF THE DRAWINGS

The technical solution, as well as beneficial advantages, of the present invention will be apparent from the following detailed description of embodiments of the present invention, with reference to the attached drawings. In the drawings:

FIG. 1 is a schematic view showing the structure of an organic p-n junction based infrared detection device according to the present invention;

FIG. 2 is a schematic view showing the arrangement of a plurality of organic p-n junctions in the organic p-n junction based infrared detection device according to the present invention;

FIG. 3 shows a molecular formula of an embodiment of infrared absorbing material used in the organic p-n junction based infrared detection device according to the present invention;

FIG. 4 is a plot showing peak of infrared absorption spectrum of the infrared absorbing material shown in FIG. 3;

FIG. 5 is a molecular formula of another embodiment of infrared absorbing material used in the organic p-n junction based infrared detection device according to the present invention;

FIG. 6 is a plot showing peak of infrared absorption spectrum of the infrared absorbing material shown in FIG. 5;

FIG. 7 is a molecular formula of an embodiment of organic n-type material used in the organic p-n junction based infrared detection device according to the present invention;

FIG. 8 is a flow chart illustrating a manufacturing method of the organic p-n junction based infrared detection device according to the present invention;

FIG. 9 is a perspective view showing an infrared image detector according to the present invention;

FIG. 10 is a schematic view showing the connection of an electrical circuit of the infrared image detector according to the present invention; and

FIG. 11 is a schematic view illustrating the principle of operation of the infrared image detector according to the present invention.

### DETAILED DESCRIPTION OF THE PREFERRED EMBODIMENTS

To further expound the technical solution adopted in the present invention and the advantages thereof, a detailed description is given to preferred embodiments of the present invention and the attached drawings.

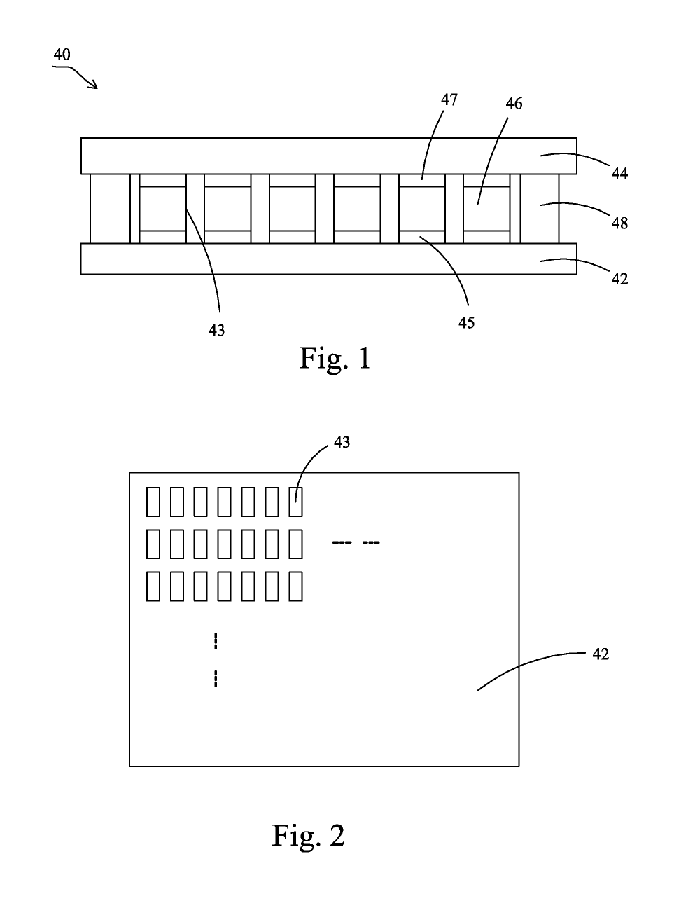

Referring to FIGS. 1-2, the present invention provides an organic p-n junction based infrared detection device 40, which adopts the next-generation solar cell technology—the organic solar cell technology—to manufacture a device having a structure comprising a dot matrix of pixel and specifically comprises: an active glass substrate 42 and a packaging glass substrate 44 that are arranged to be parallel to and opposite to each other, a plurality of organic p-n junctions 43 arranged between the active glass substrate 42 and the packaging glass substrate 44, and a package material 48 arranged on a circumferential marginal area of the active glass substrate 42 and the packaging glass substrate 44. The plurality of organic p-n junctions 43 is arranged in the form of a matrix to help improve the sensitivity of an infrared image detector 10 that uses the organic p-n junction based infrared detection device 40. The package material 48 is used to seal and bond the active glass substrate 42 and the packaging glass substrate 44 together to prevent invasion of water and oxygen into the interior of the packaged infrared detection device 40 so as to maintain the performance of the infrared detection device 40 and extend the life span thereof.

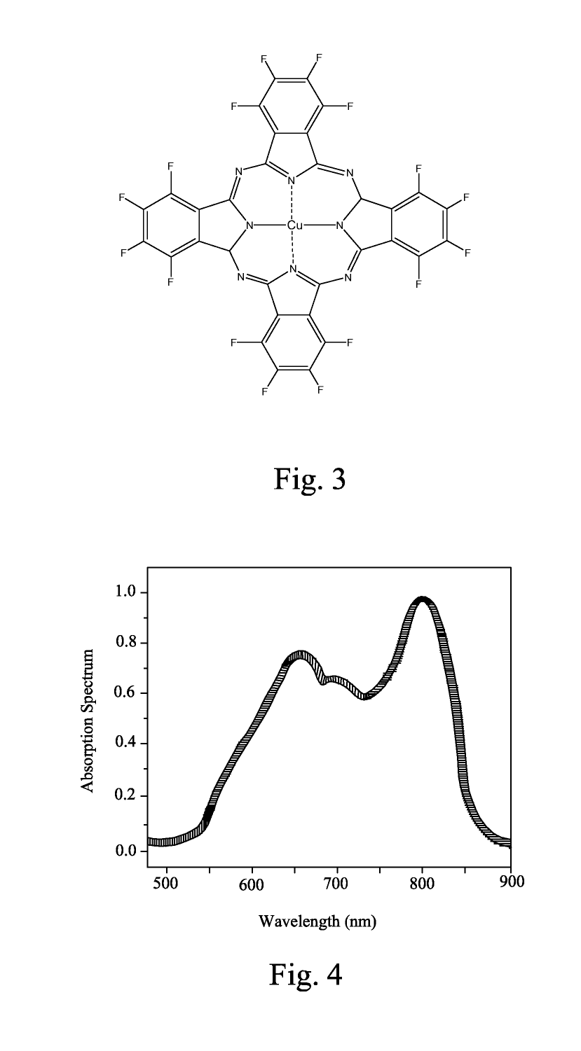

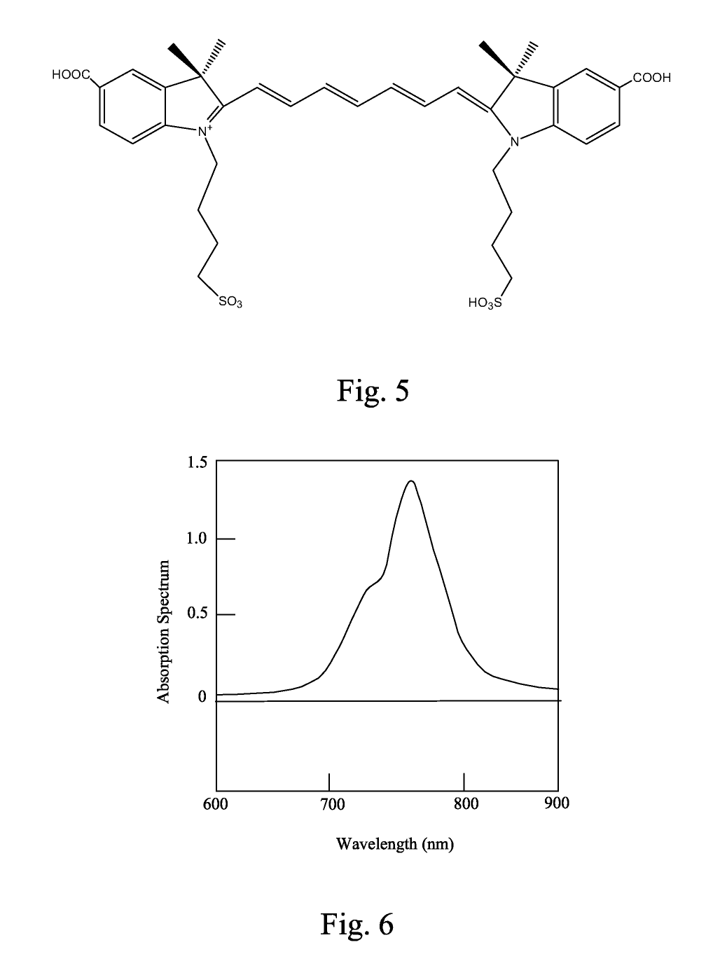

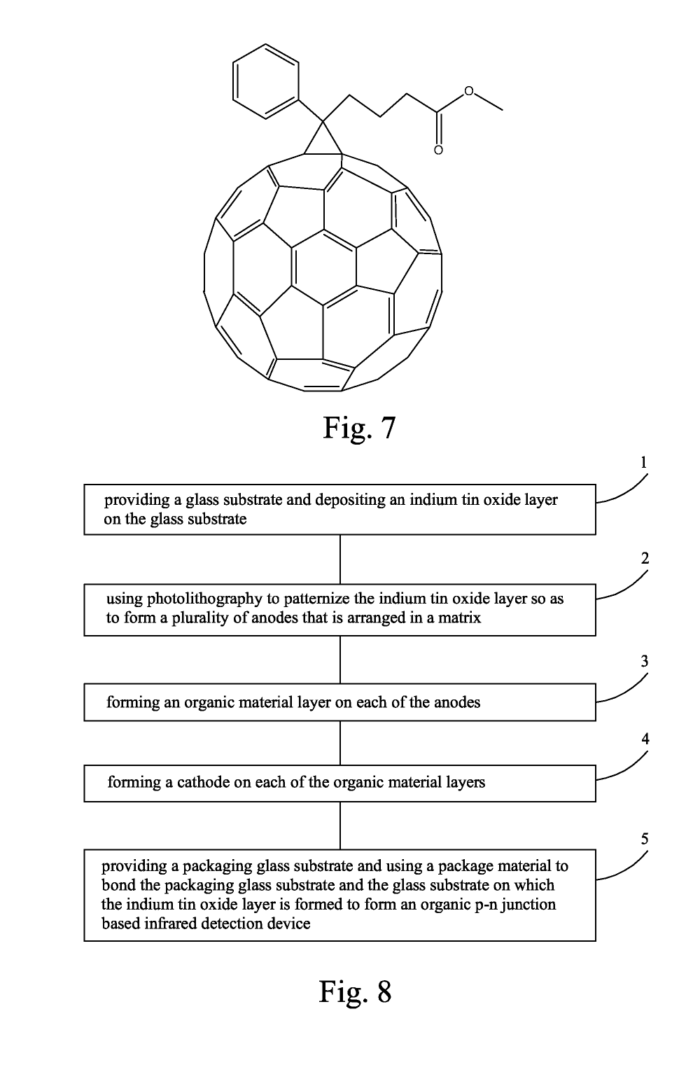

Each of the organic p-n junctions 43 comprises: an anode 45 mounted on the active glass substrate 42, an organic material layer 46 arranged on the anode 45, and a cathode 47 arranged on the organic material layer 46. The cathode 47 and the packaging glass substrate 44 are positioned against each other. The organic material layer 46 has a thickness of 50-200 nanometers and comprises an organic p-type material and an organic n-type material in such a way that the organic p-type material and the organic n-type material form an interface therebetween. The organic material layer 46, after absorbing an infrared light, forms excitons and the excitons are separated into holes and electrons at the interface, where the electrons flow toward the cathode and the holes flow toward the anode to thereby form a photo current. The organic p-type material is an infrared absorbing material and the infrared absorbing material is preferably copper hexadecafluorophthalocyanine (CuPcF₁₆), of which the molecular formula is shown in FIG. 3 and which can form a solid film having a peak value of infrared absorption spectrum that is 793 nm, as shown in FIG. 4. The infrared absorbing material can alternatively be 5,5′-dicarboxy-1,1′-disulfobutyl-3,3,3′,3′-tetramethylindotricarbocyanine (DCDSTCY), of which the molecular formula is shown in FIG. 5 and which can form a solution having a peak value of infrared absorption spectrum that is 755 nm, as shown in FIG. 6. As shown in FIG. 7, the organic n-type material is preferably a fullerene derivative, [6,6]-phenyl-C61-butyric acid methyl ester (PCBM), which has excellent solubility and also has better electron transportation capability and higher electron affinity, the energy level of HOMO (highest occupied molecular orbital) being 6.0 eV, the energy level of LUMO (lowest unoccupied molecular orbital) being 4.2 eV, and carrier mobility being 10⁻³ cm²/V·s, so as to make it an excellent electron transportation material for solar cells.

Referring collectively to FIGS. 1, 2, and 8, the present invention also provides a manufacturing method of the organic p-n junction based infrared detection device 40, which specifically comprises the following steps:

Step 1: providing a glass substrate and depositing an indium tin oxide (ITO) layer on the glass substrate.

Physical vapor deposition (PVD) is used to deposit a layer of indium tin oxide having a thickness of around 150 nm on the glass substrate to form the indium tin oxide layer.

Step 2: using photolithography to patternize the indium tin oxide layer so as to form a plurality of anodes 45 that is arranged in a matrix.

Step 3: forming an organic material layer 46 on each of the anodes 45.

The organic material layer 46 has a thickness of 50-200 nanometers. In this step, co-evaporation of vacuum deposition technology is used to simultaneously deposit an organic p-type material and an organic n-type material on each of the anodes 45 to form the organic material layer 46; alternatively, vacuum deposition is adopted to first deposit an organic p-type material on each of the anodes 45 and then, a layer of organic n-type material is deposited on the organic p-type material to form the organic material layer 46, wherein a ratio between the organic p-type material and the organic n-type material is 5-7:3-5 and after the deposition, the organic p-type material shows a thickness of 30-150 nanometers and the organic n-type material has a thickness of 20-50 nanometers.

In this step, it is also possible to collectively dissolve an organic p-type material and an organic n-type material in an organic solvent. And, then, a mask and the indium tin oxide layer are laminated together and the organic solvent in which the organic p-type material and the organic n-type material are dissolved is applied on the mask. After the organic solvent is dried, the mask is removed to thus form the organic material layer 46, wherein a ratio between the organic p-type material and the organic n-type material is 5-7:3-5.

The organic p-type material is an infrared absorbing material and the infrared absorbing material is preferably copper hexadecafluorophthalocyanine (CuPcF₁₆), of which the molecular formula is shown in FIG. 3 and which can form a solid film having a peak value of infrared absorption spectrum that is 793 nm, as shown in FIG. 4. The infrared absorbing material can alternatively be DCDSTCY, of which the molecular formula is shown in FIG. 5 and which can form a solution having a peak value of infrared absorption spectrum that is 755 nm, as shown in FIG. 6. As shown in FIG. 7, the organic n-type material is preferably a fullerene derivative (PCBM), which has excellent solubility and also has better electron transportation capability and higher electron affinity, the energy level of HOMO (highest occupied molecular orbital) being 6.0 eV, the energy level of LUMO (lowest unoccupied molecular orbital) being 4.2 eV, and carrier mobility being 10⁻³ cm²/V·s, so as to make it an excellent electron transportation material for solar cells.

Step 4: forming a cathode 47 on each of the organic material layers 46.

In the instant embodiment, an aluminum metal material is used to form the cathode 47. The metal aluminum is deposited with vacuum deposition on each of the organic material layers 46.

Step 5: providing a packaging glass substrate 44 and using a package material 48 to bond the packaging glass substrate 44 and the glass substrate (which is an active glass substrate 42) on which the indium tin oxide layer is formed to form an organic p-n junction based infrared detection device 40.

The cathodes 47 and the packaging glass substrate 44 are positioned against each other.

In this step, it is possible to apply a resin frame on a circumferential edge of the packaging glass substrate 44 and laminating the packaging glass substrate 44 on which the resin frame is applied and the glass substrate on which the indium tin oxide layer is formed together and subjecting them to irradiation of ultraviolet light to cure the resin frame thereby hermetically package the packaging glass substrate 44 and the glass substrate on which the indium tin oxide layer is formed together to form the organic p-n junction based infrared detection device 40.

In this step, it is alternatively possible to apply a meltable adhesive or a metal adhesive on a circumferential edge of the packaging glass substrate 44 and heat and dry the adhesive. The glass substrate on which the indium tin oxide layer is formed and the packaging glass substrate 44 are assembled together. Carbon dioxide laser or infrared laser having a laser wavelength of 800-1200 nm is applied to melt the dried adhesive so as to hermetically bond the glass substrate on which the indium tin oxide layer is formed and the packaging glass substrate 44 together to form the organic p-n junction based infrared detection device 40.

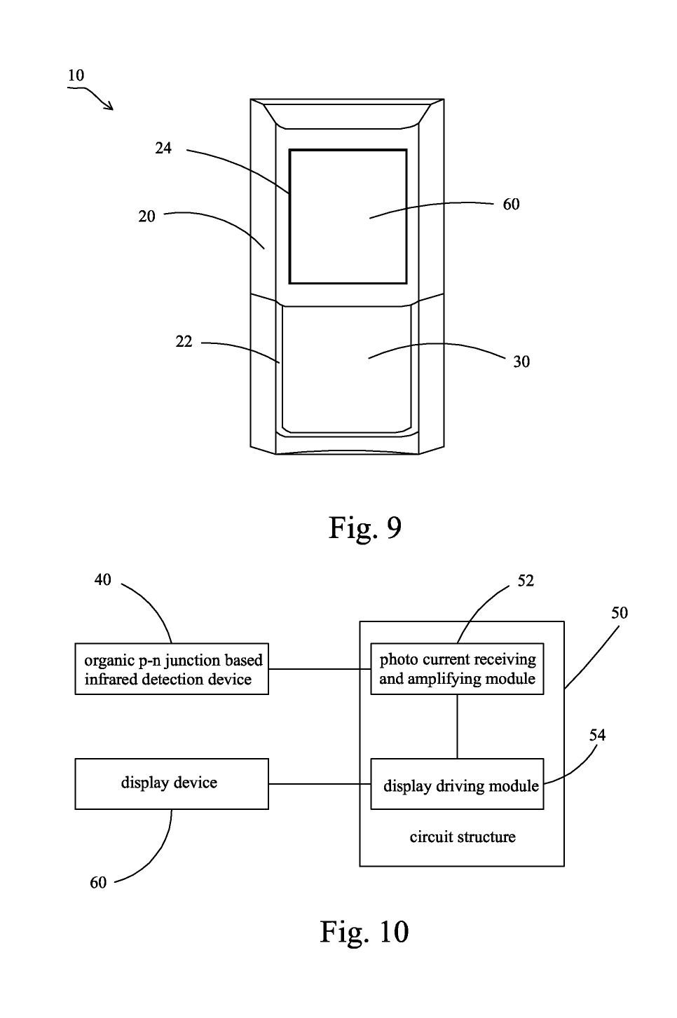

Referring to FIGS. 1-7 and 9-10, the present invention further provides an infrared image detector 10 that uses the organic p-n junction based infrared detection device and comprises: an enclosure 20, an infrared-pass filter 30 mounted on the enclosure 20, an organic p-n junction based infrared detection device 40 mounted in the enclosure 20 and corresponding to the infrared-pass filter 30, a circuit structure 50 mounted in the enclosure 20 and electrically connected to the organic p-n junction based infrared detection device 40, and a display device 60 mounted on the enclosure 20 and electrically connected to the circuit structure 50. The organic p-n junction based infrared detection device 40 comprises: an active glass substrate 42 and a packaging glass substrate 44 that are arranged to be parallel to and opposite to each other, a plurality of organic p-n junctions 43 arranged between the active glass substrate 42 and the packaging glass substrate 44, and a package material 48 arranged on a circumferential marginal area of the active glass substrate 42 and the packaging glass substrate 44. The plurality of organic p-n junctions 43 is arranged in the form of a matrix to help improve the performance of the infrared image detector 10. The package material 48 is used to seal and bond the active glass substrate 42 and the packaging glass substrate 44 together to prevent invasion of water and oxygen into the interior of the packaged infrared detection device 40 so as to maintain the performance of the infrared detection device 40 and extend the life span of the organic p-n junction based infrared detection device 40.

The active glass substrate 42 of the organic p-n junction based infrared detection device 40 is arranged to face the infrared-pass filter 30, whereby an infrared light 70 from the surroundings, after being filtered by the infrared-pass filter 30, transmits through the active glass substrate 42 into the organic p-n junction based infrared detection device 40. The enclosure 20 comprises a first opening 22 and a second opening 24 formed thereon. The infrared-pass filter 30 is mounted in the first opening 22 to allow the external infrared light 70 to directly irradiate the surface of the infrared-pass filter 30. The display device 60 is selectively mounted in the second opening 24 to display the intensity of the infrared light 70 detected by the infrared image detector 10, namely monochromatically displaying an image visible to human eyes. Further, the display device 60 can alternatively be separate from the enclosure 20 and arranged individually so as to be installed at a site ready for observation by a user to thereby enhance the operability thereof.

The circuit structure 50 comprises: a photo current receiving and amplifying module 52 electrically connected to the organic p-n junction based infrared detection device 40 and a display driving module 54 electrically connected to the photo current receiving and amplifying module 52. The organic p-n junction based infrared detection device 40, when being irradiated by the infrared light 70, generates excitons (electron-hole pairs). The excitons will eventually separate and form a photo current. The photo current receiving and amplifying module 52 receives the magnitude of the photo current, namely sampling the intensity of the infrared light 70 irradiating the organic p-n junction based infrared detection device 40, and subjects the photo current to amplification for subsequent transmission to the display driving module 54. The display driving module 54 is also electrically connected to the display device 60 so as to drive the display device 60 to monochromatically display an image according to the signal of the photo current, thereby displaying the intensity of the infrared light 70 irradiating the organic p-n junction based infrared detection device 40.

Each of the organic p-n junctions 43 comprises: an anode 45 mounted on the active glass substrate 42, an organic material layer 46 arranged on the anode 45, and a cathode 47 arranged on the organic material layer 46. The cathode 47 and the packaging glass substrate 44 are positioned against each other. The organic material layer 46 comprises an organic p-type material and an organic n-type material in such a way that the organic p-type material and the organic n-type material form an interface therebetween. The excitons are separated into holes and electrons at the interface, where the electrons flow toward the cathode and the holes flow toward the anode to thereby form the photo current. The organic p-type material is an infrared absorbing material and the infrared absorbing material is preferably copper hexadecafluorophthalocyanine (CuPcF₁₆), of which the molecular formula is shown in FIG. 3 and which can form a solid film having a peak value of infrared absorption spectrum that is 793 nm, as shown in FIG. 4. The infrared absorbing material can alternatively be DCDSTCY, of which the molecular formula is shown in FIG. 5 and which can form a solution having a peak value of infrared absorption spectrum that is 755 nm, as shown in FIG. 6. As shown in FIG. 7, the organic n-type material is preferably a fullerene derivative (PCBM), which has excellent solubility and also has better electron transportation capability and higher electron affinity, the energy level of HOMO (highest occupied molecular orbital) being 6.0 eV, the energy level of LUMO (lowest unoccupied molecular orbital) being 4.2 eV, and carrier mobility being 10⁻³ cm²/V·s, so as to make it an excellent electron transportation material for solar cells.

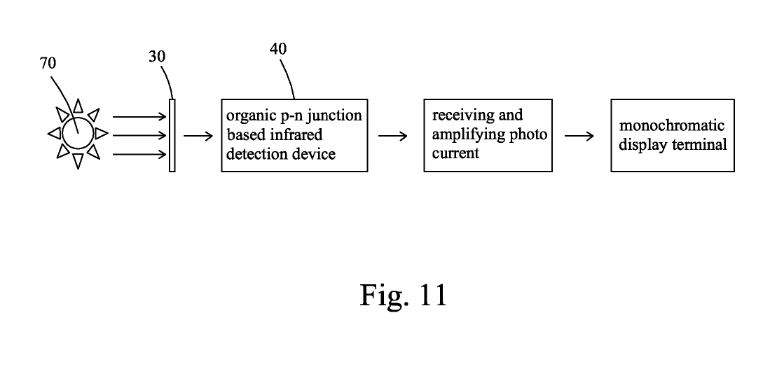

Referring to FIG. 11, a specific way for practicing the present invention is as follows: The infrared-pass filter 30 filters off the visible lights (having a wavelength range of 390 nm-760 nm) and electromagnetic waves having even shorter wavelength. The organic p-n junctions 43 absorb radiating photons of the infrared light 70 to form excitons (electron-hole pairs) and the excitons separate at the interface between the organic p material and the organic n material to allow the electrons to flow to the cathode and the holes flowing to the anode. The circuit structure 50 receives the photo current, which is subjected to amplification to finally display a monochromatic image that is visible to human eyes on the display device 60. The image has a high contrast and a strong power for identifying details. The infrared detection device 40 has a simple manufacturing process and a low manufacturing cost and the materials used are of low toxicity, inexpensive, diversified, and of various sources and the infrared detection device 40 can be manufactured on a polycrystalline, amorphous, flexible substrate and can expand the imaging angle.

The present invention provides an infrared image detector 10 that uses the organic p-n junction based infrared detection device 40, enabling detection of a target in the nighttime or thick fog/cloud to further enable the identification of a masqueraded target and a target moving in a high speed and besides military applications, that can be widely used in civil fields including industry, agriculture, medicine, fire fighting, archeology, transportation, geology, and public security investigation. Examples of application are given in the following:

(1) It can be used in inspection and maintenance of power systems and air and space systems.

(2) It can be used in quality control for businesses of petrochemical industry, steel industry, and electronic industry.

(3) It can be used to monitor household power lines and water leak of buildings.

(4) It can be used in a battle field, where soldiers may transmit and receive infrared signals in the nighttime without being detected by the enemies and possessing the capability of observation through fog and rain so as to be applicable to survey of airplanes, vessels, and tanks of the enemy.

In summary, the present invention provides an organic p-n junction based infrared detection device and a manufacturing method thereof and an infrared image detector using the device, wherein organic p-n junctions absorb radiating photons of an infrared light to form excitons (electron-hole pairs) and the excitons separate at the interface between the organic p material and the organic n material to allow the electrons to flow to the cathode and the holes flowing to the anode, so as to form a photo current, and a circuit structure receives the photo current, which is subjected to amplification to finally display a monochromatic image that is visible to human eyes on a display device. The image has a high contrast and a strong power for identifying details. The infrared detection device has a simple manufacturing process and a low manufacturing cost and the materials used are of low toxicity, inexpensive, diversified, and of various sources and the infrared detection device 40 can be manufactured on a polycrystalline, amorphous, flexible substrate and can expand the imaging angle.

Based on the description given above, those having ordinary skills in the art may easily contemplate various changes and modifications of the technical solution and technical ideas of the present invention and all these changes and modifications are considered within the protection scope of right for the present invention.

What is claimed is:

1. An organic p-n junction based infrared detection device, comprising: an active glass substrate and a packaging glass substrate that are arranged to be parallel to and opposite to each other, a plurality of organic p-n junctions arranged between the active glass substrate and the packaging glass substrate, and a package material arranged on a circumferential marginal area of the active glass substrate and the packaging glass substrate, the plurality of organic p-n junctions being arranged in a matrix on the active glass substrate.

2. The organic p-n junction based infrared detection device as claimed in claim 1, wherein each of the organic p-n junctions comprises: an anode mounted on the active glass substrate, an organic material layer arranged on the anode, and a cathode arranged on the organic material layer, the cathode and the packaging glass substrate being positioned against each other.

3. The organic p-n junction based infrared detection device as claimed in claim 2, wherein the organic material layer comprises an organic p-type material and an organic n-type material, the organic p-type material being an infrared absorbing material, the infrared absorbing material comprising copper hexadecafluorophthalocyanine or DCDSTCY, the organic n-type material comprising a fullerene derivative.

4. A manufacturing method of an organic p-n junction based infrared detection device, comprising the following steps:
(1) providing a glass substrate and depositing an indium tin oxide layer on the glass substrate;
(2) using photolithography to patternize the indium tin oxide layer so as to form a plurality of anodes that is arranged in a matrix;
(3) forming an organic material layer on each of the anodes;
(4) forming a cathode on each of the organic material layers; and
(5) providing a packaging glass substrate and using a package material to bond the packaging glass substrate and the glass substrate on which the indium tin oxide layer is formed to form an organic p-n junction based infrared detection device.

5. The manufacturing method of an organic p-n junction based infrared detection device as claimed in claim 4, wherein in step (3), co-evaporation of vacuum deposition technology is used to simultaneously deposit an organic p-type material and an organic n-type material on each of the anodes to form the organic material layer; or, in step (3), vacuum deposition is adopted to first deposit an organic p-type material on each of the anodes and then, a layer of organic n-type material is deposited on the organic p-type material to form the organic material layer, wherein a ratio between the organic p-type material and the organic n-type material is 5-7:3-5 and after the deposition, the organic p-type material shows a thickness of 30-150 nanometers and the organic n-type material has a thickness of 20-50 nanometers.

6. The manufacturing method of an organic p-n junction based infrared detection device as claimed in claim 4, wherein in step (3), an organic p-type material and an organic n-type material are collectively dissolved in an organic solvent and then, a mask and the indium tin oxide layer are laminated together and the organic solvent in which the organic p-type material and the organic n-type material are dissolved is applied on the mask, and after the organic solvent is dried, the mask is removed to thus form the organic material layer, wherein a ratio between the organic p-type material and the organic n-type material is 5-7:3-5.

7. The manufacturing method of an organic p-n junction based infrared detection device as claimed in claim 4, wherein in step (5), a resin frame is applied on a circumferential edge of the packaging glass substrate and the packaging glass substrate on which the resin frame is applied and the glass substrate on which the indium tin oxide layer is formed are laminated together and are subjected to irradiation of ultraviolet light to cure the resin frame thereby hermetically package the packaging glass substrate and the glass substrate on which the indium tin oxide layer is formed together; or, a meltable adhesive or a metal adhesive is applied on a circumferential edge of the packaging glass substrate and the adhesive is heated and dried, and the glass substrate on which the indium tin oxide layer is formed and the packaging glass substrate are assembled together, and carbon dioxide laser or infrared laser having a laser wavelength of 800-1200 nm is applied to melt the dried adhesive so as to hermetically bond the glass substrate on which the indium tin oxide layer is formed and the packaging glass substrate together.

8. The manufacturing method of an organic p-n junction based infrared detection device as claimed in claim 4, wherein the organic material layer comprises an organic p-type material and an organic n-type material, the organic p-type material being an infrared absorbing material, the infrared absorbing material comprising copper hexadecafluorophthalocyanine or DCDSTCY, the organic n-type material comprising a fullerene derivative.

9. An infrared image detector using an organic p-n junction based infrared detection device, comprising: an enclosure, an infrared-pass filter mounted on the enclosure, an organic p-n junction based infrared detection device mounted in the enclosure and corresponding to the infrared-pass filter, a circuit structure mounted in the enclosure and electrically connected to the organic p-n junction based infrared detection device, and a display device mounted on the enclosure and electrically connected to the circuit structure, the organic p-n junction based infrared detection device comprising: an active glass substrate and a packaging glass substrate that are arranged to be parallel to and opposite to each other, a plurality of organic p-n junctions arranged between the active glass substrate and the packaging glass substrate, and a package material arranged on a circumferential marginal area of the active glass substrate and the packaging glass substrate, the plurality of organic p-n junctions being arranged in the form of a matrix on the active glass substrate, the circuit structure comprising: a photo current receiving and amplifying module electrically connected to the organic p-n junction based infrared detection device and a display driving module electrically connected to the photo current receiving and amplifying module, the display driving module being further electrically connected to the display device.

10. The infrared image detector using an organic p-n junction based infrared detection device as claimed in claim 9, wherein the active glass substrate of the organic p-n junction based infrared detection device is arranged to face the infrared-pass filter, the enclosure comprising a first opening and a second opening formed thereon, the infrared-pass filter being mounted in the first opening, the display device being mounted in the second opening, each of the organic p-n junctions comprising: an anode mounted on the active glass substrate, an organic material layer arranged on the anode, and a cathode arranged on the organic material layer, the cathode and the packaging glass substrate being positioned against each other, the organic material layer comprising an organic p-type material and an organic n-type material, the organic p-type material being an infrared absorbing material, the infrared absorbing material comprising copper hexadecafluorophthalocyanine or DCDSTCY, the organic n-type material comprising a fullerene derivative.
